(19) United States
(12) Patent Application Publication
(10) Pub. No.: US 2026/0363124 A1
(43) Pub. Date: Nov. 12, 2026

(54) PACKAGING SUBSTRATE AND SEMICONDUCTOR PACKAGE COMPRISING THE SAME

(71) Applicant: Absolics Inc., Covington, GA (US)

(72) Inventors: SI HUN LEE, Covington, GA (US); JE HYEONG PARK, Covington, GA (US)

(73) Assignee: Absolics Inc., Covington, GA (US)

(21) Appl. No.: 19/669,929

(22) Filed: May 6, 2026

Related U.S. Application Data
(60) Provisional application No. 63/801,840, filed on May 8, 2025.

(51) Int. Cl. H10W 70/695; H10W 70/685; H10W 70/692

(52) U.S. Cl. CPC H10W 70/695; H10W 70/686; H10W 70/692

(57) ABSTRACT

A packaging substrate according to the present disclosure comprises a glass core and a first complex insulating layer disposed on the glass core. The first complex insulating layer comprises an elastic insulating layer and a base insulating layer disposed on the elastic insulating layer. A ratio of a thickness of the glass core to a thickness of the first complex insulating layer is 8 to 30. A glass transition temperature of the elastic insulating layer is 30 °C to 85 °C. In this case, it may suppress occurrence of excessive warpage in the packaging substrate, and may provide a packaging substrate having excellent electrical reliability.

### CROSS-REFERENCE TO RELATED APPLICATION

This application claims the priority benefit under 35 USC § 119(e) of U.S. Provisional Patent Application No. 63/801,840, filed on May 8, 2025, the entire disclosure of which is incorporated herein by reference for all purposes.

### BACKGROUND

### Technical Field

The present disclosure relates to a packaging substrate, a semiconductor package comprising the same, and the like.

### Description of Related Art

In manufacturing an electronic component, implementing a circuit on a semiconductor wafer is referred to as a front-end process (FE: Front-End), and assembling the wafer into a state usable in an actual product is referred to as a back-end process (BE: Back-End), and a packaging process is included in the back-end process.

Recently, four core technologies of the semiconductor industry that have enabled rapid development of electronic products are semiconductor technology, semiconductor packaging technology, manufacturing process technology, and software technology. Semiconductor technology has been developed in various forms such as line widths of micro or less and nano units, ten million or more cells, high-speed operation, and large heat dissipation, but a technology for perfectly packaging the same has not been sufficiently supported relatively. Accordingly, electrical performance of a semiconductor may be determined by packaging technology and electrical connection resulting therefrom rather than performance of the semiconductor technology itself.

Ceramic or resin is applied as a material of a packaging substrate. In the case of a ceramic substrate, it is not easy to mount a high-performance high-frequency semiconductor device because a resistance value is high or a dielectric constant is high. In the case of a resin substrate, although a high-performance high-frequency semiconductor device may be mounted relatively, there is a limit in reduction of pitch of wiring.

Recently, studies applying silicon or glass as a high-end packaging substrate are in progress. Through-holes are formed in a silicon or glass substrate, and a conductive material is applied to the through-holes, whereby a wiring length between a device and a motherboard may become short and excellent electrical characteristics may be obtained.

### SUMMARY

A packaging substrate according to one embodiment of the present specification comprises a glass core and a first complex insulating layer disposed on the glass core.

The first complex insulating layer comprises an elastic insulating layer and a base insulating layer disposed on the elastic insulating layer.

A ratio of a thickness of the glass core to a thickness of the first complex insulating layer is 8 to 30.

A glass transition temperature of the elastic insulating layer is 30 °C to 85 °C.

A Dcp value, which is a deviation in thermal expansion characteristic of Equation 1 below, of the first complex insulating layer may be 4 ppm/°C to 15 ppm/°C.

Dcp=Tr_{b}×CTE_{b}−Trₑ×CTEₑ [Equation 1]

In Equation 1 above, the Tr_{b} is a ratio of a thickness of the base insulating layer to a thickness of the first complex insulating layer, the CTE_{b} is a coefficient of thermal expansion of the base insulating layer measured at 25 °C to 150 °C (unit: ppm/°C), the Trₑ is a ratio of a thickness of the elastic insulating layer to a thickness of the first complex insulating layer, and the CTEₑ is a coefficient of thermal expansion of the elastic insulating layer measured at 25 °C to 150 °C (unit: ppm/°C).

An elongation of the elastic insulating layer may be 25% or more.

A ratio of a thickness of the elastic insulating layer to a thickness of the base insulating layer may be 0.05 to 0.3.

A thickness of the elastic insulating layer may be 1 μm to 15 μm.

The elastic insulating layer may be disposed in contact with at least a part of an upper surface of the glass core.

A dielectric constant Dk of the base insulating layer at frequency of 5.8 GHz may be 4 or less.

A dielectric dissipation factor Df of the base insulating layer at frequency of 5.8 GHz may be 0.01 or less.

The elastic insulating layer may comprise a bis-maleimide resin.

The packaging substrate may comprise two or more layers of the first complex insulating layer.

The packaging substrate may further comprise a wiring layer disposed between the first complex insulating layers.

An upper surface of the wiring layer may be disposed in contact with a lower surface of the first complex insulating layer disposed on the wiring layer.

A 90° peel strength of the wiring layer with respect to the first complex insulating layer disposed on the wiring layer may be 1 kgf/cm or more.

### BRIEF DESCRIPTION OF THE DRAWINGS

FIG. 1 is a cross-sectional view illustrating a packaging substrate according to one embodiment of the present disclosure.

FIG. 2 is a cross-sectional view illustrating a packaging substrate according to another embodiment of the present disclosure.

FIG. 3 is a cross-sectional view illustrating a packaging substrate according to still another embodiment of the present disclosure.

### DESCRIPTION OF THE EMBODIMENTS

Hereinafter, embodiments will be described in detail with reference to the accompanying drawings so that a person having ordinary skill in the art to which the present invention pertains may easily carry out the same. However, the present invention may be embodied in various different forms and is not limited to the embodiments described herein. Throughout the specification, like reference numerals designate like parts.

Throughout the present specification, the term “combination thereof” included in a Markush-type expression means one or more mixtures or combinations selected from the group consisting of components recited in the Markush-type expression, and means including one or more selected from the group consisting of the components.

Throughout the present specification, terms such as “first,” “second,” or “A,” “B” are used to distinguish identical terms from each other. In addition, a singular expression includes a plural expression unless the context clearly indicates otherwise.

In the present specification, “~based” may mean including a compound corresponding to “~” or a derivative of “~” in a compound.

In the present specification, the meaning that B is positioned on A means that B is positioned directly in contact with A on A, or B is positioned on A while another layer is positioned therebetween, and is not construed as being limited to B being positioned in contact with a surface of A.

In the present specification, the meaning that A is connected to B on A means that A and B are directly connected or connected through another component between A and B, and unless specifically stated otherwise, is not construed as being limited to A and B being directly connected.

In the present specification, a singular expression, unless specifically stated otherwise, is construed as meaning including singular or plural interpreted in context.

In the present specification, in the drawings, shapes, relative sizes, angles, and the like of respective components are illustrative and may be exaggerated for explanation purposes, and rights are not construed as being limited to the drawings.

In the present specification, that A and B are adjacent means that A and B are positioned in contact with each other, or A and B are not in contact with each other but are positioned close to each other. Unless specifically stated otherwise, the expression that A and B are adjacent is not construed as being limited to A and B being positioned in contact with each other.

In the present specification, unless specifically stated otherwise, physical property values of respective components in a packaging substrate are construed as measured at room temperature. Room temperature is 20 °C to 25 °C.

Hereinafter, the present disclosure will be described in detail.

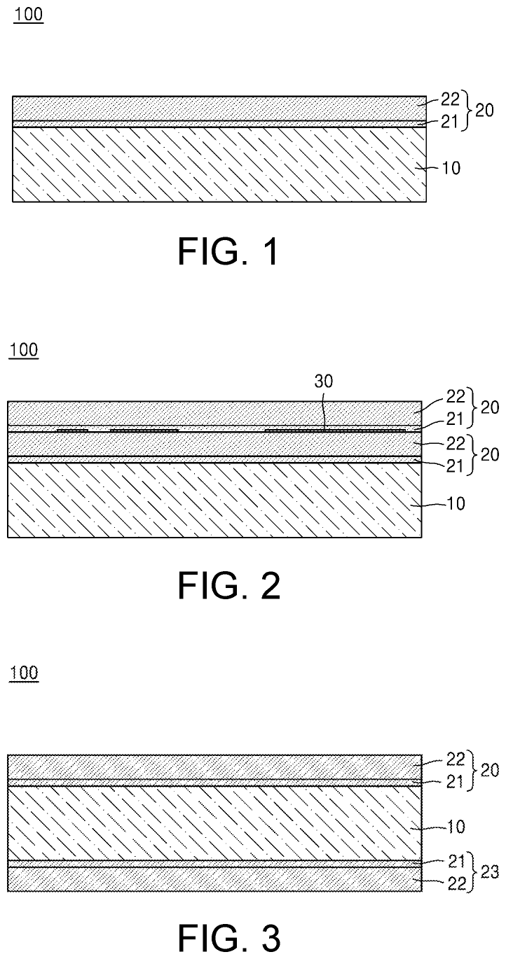

FIG. 1 is a cross-sectional view illustrating a packaging substrate according to one embodiment of the present disclosure. Hereinafter, the present disclosure will be described with reference to FIG. 1.

### Glass Core

A packaging substrate 100 according to the present disclosure may comprise a glass core 10.

The glass core 10 may have a shape of a glass substrate. The glass core 10 may, for example, be applied with alkali borosilicate sheet glass, alkali-free borosilicate sheet glass, alkali-free alkalito borosilicate sheet glass, and the like, and any sheet glass applied as an electronic component may be applied. The glass core 10 may be applied with a glass substrate for an electronic device, and may, for example, be one manufactured by Schott, AGC, Corning, and the like, but is not limited thereto.

The glass core 10 may comprise a through via (not shown) penetrating in a thickness direction of the glass core 10.

The through via is composed of an inner space (not shown) and a via inner circumferential surface (not shown) surrounding the inner space. The inner space means an empty space, and the via inner circumferential surface means a surface of the glass core 10 formed inside the through via.

The through via may have a diameter changing in the thickness direction of the glass core 10. The through via may have a substantially uniform diameter in the thickness direction of the glass core 10.

A surface of the glass core 10 may comprise an upper surface and a side surface connected to the upper surface and formed in a thickness direction of the glass core 10. The surface of the glass core 10 may comprise a lower surface facing the upper surface.

That the side surface is formed in the thickness direction of the glass core 10 is construed as meaning including not only that the side surface forms a perpendicular angle with the upper surface of the glass core 10, but also that at least a part of the side surface forms an angle other than 90 degrees (an inclination angle) with the upper surface.

The side surface may be a flat surface or may be a curved surface.

The glass core 10 may comprise a cavity (not shown), which is a space formed by recessing an inside thereof.

The cavity may be formed by recessing a part of an upper surface side and/or a lower surface side of the glass core 10 in the thickness direction of the glass core 10, or may penetrate in the thickness direction of the glass core 10.

A device may be mounted in the cavity so that the packaging substrate 100 and the device may be electrically connected. As the device, not only semiconductor devices such as a CPU, a GPU, and a memory chip, but also a capacitor device, a transistor device, an impedance device, and other modules may be applied. That is, any semiconductor device mounted in a semiconductor apparatus may be applied as the device without limitation.

A thickness of the glass core 10 may be 100 μm or more. The thickness may be 200 μm or more. The thickness may be 300 μm or more. The thickness may be 3000 μm or less. The thickness may be 2000 μm or less. The thickness may be 1000 μm or less. In this case, in a process of forming an insulating layer on the glass core 10, the glass core 10 may not be easily warped and may contribute to providing the packaging substrate 100 having a thinner thickness.

### Properties and Structure of Complex Insulating Layer

The packaging substrate 100 comprises a first complex insulating layer 20 disposed on the glass core 10. The first complex insulating layer 20 comprises an elastic insulating layer 21 and a base insulating layer 22 disposed on the elastic insulating layer 21.

The elastic insulating layer 21 is a layer having insulating properties and having higher elasticity than the base insulating layer 22. The elastic insulating layer 21 may function as a buffer layer that relieves stress applied to the glass core 10 in an atmosphere in which temperature rise and fall are repeated.

The base insulating layer 22 is a layer having insulating properties and supporting a wiring layer to be disposed on the first complex insulating layer 20.

The first complex insulating layer 20 may be disposed in contact with at least a part of the upper surface of the glass core 10. When another component such as a wiring layer is formed on the upper surface of the glass core 10, the first complex insulating layer 20 may be disposed in contact with the upper surface of the glass core 10 not covered by the wiring layer and the like.

The elastic insulating layer 21 may be disposed in contact with at least a part of the upper surface of the glass core 10. When another component such as a wiring layer is formed on the upper surface of the glass core 10, the elastic insulating layer 21 may be disposed in contact with the upper surface of the glass core 10 not covered by the wiring layer and the like.

At least a part of the base insulating layer 22 may be disposed in contact with the elastic insulating layer 21. The base insulating layer 22 may be disposed in contact with the elastic insulating layer 21. An entire lower surface of the base insulating layer 22 may be disposed in contact with an upper surface of the elastic insulating layer 21. That is, within the first complex insulating layer 20, another component may not be disposed between the elastic insulating layer 21 and the base insulating layer 22.

The present disclosure may control a thickness ratio of the first complex insulating layer 20 and the glass core 10, such that the glass core 10 may not be easily warped by stress generated in a curing process of the first complex insulating layer 20.

A ratio of a thickness of the glass core 10 to a thickness of the first complex insulating layer 20 may be 8 to 30. The ratio may be 10 or more. The ratio may be 13 or more. The ratio may be 25 or less. The ratio may be 22 or less. The ratio may be 20 or less. A packaging substrate having these characteristics may have a thin thickness, while the glass core 10 may not be easily warped in a lamination and curing process of the first complex insulating layer 20.

The thickness of the first complex insulating layer 20 means a thickness of one layer of the first complex insulating layer 20.

The first complex insulating layer 20 may comprise the elastic insulating layer 21 of which a glass transition temperature is controlled within a range preset in the present disclosure. When the first complex insulating layer 20 has the above characteristics, the elastic insulating layer 21 may have sufficient elasticity to function as a buffer layer for reducing stress of the glass core 10 within the first complex insulating layer 20. Specifically, when the base insulating layer 22 is formed through a curing process and the like, the elastic insulating layer 21 may stably reduce a force applied by the base insulating layer 22 to the glass core 10.

A glass transition temperature of the elastic insulating layer 21 may be 30 °C to 85 °C. The glass transition temperature may be 35 °C or more. The glass transition temperature may be 40 °C or more. The glass transition temperature may be 80 °C or less. The glass transition temperature may be 75 °C or less. In this case, the glass core 10 may stably maintain excellent flatness.

A glass transition temperature of the base insulating layer 22 may be 100 °C or more. The glass transition temperature may be 110 °C or more. The glass transition temperature may be 120 °C or more. The glass transition temperature may be 130 °C or more. The glass transition temperature may be 140 °C or more. The glass transition temperature may be 230 °C or less. The glass transition temperature may be 220 °C or less. The glass transition temperature may be 210 °C or less. The glass transition temperature may be 200 °C or less. The glass transition temperature may be 190 °C or less. In this case, even in a high-temperature atmosphere, a wiring layer disposed on the base insulating layer 22 may be stably fixed and maintained.

The glass transition temperatures of the elastic insulating layer 21 and the base insulating layer 22 are measured by a thermomechanical analyzer (TMA) using JIS-C6481 as a standard.

Upon measurement, a tensile method is performed as prescribed in IPC-TM650, and a temperature increase rate is applied at 10 °C/min. The glass transition temperatures are measured within a range of 25 °C to 150 °C.

A Dcp value, which is a deviation in thermal expansion characteristic of Equation 1 below, of the first complex insulating layer 20 may be 4 ppm/°C to 15 ppm/°C.

Dcp=Tr_{b}×CTE_{b}−Trₑ×CTEₑ [Equation 1]

In Equation 1 above, the Tr_{b} is a ratio of a thickness of the base insulating layer 22 to a thickness of the first complex insulating layer 20, the CTE_{b} is a coefficient of thermal expansion of the base insulating layer 22 measured at 25 °C to 150 °C (unit: ppm/°C), the Trₑ is a ratio of a thickness of the elastic insulating layer 21 to a thickness of the first complex insulating layer 20, and the CTEₑ is a coefficient of thermal expansion of the elastic insulating layer 21 measured at 25 °C to 150 °C (unit: ppm/°C).

The coefficient of thermal expansion is an x-y direction coefficient of thermal expansion (CTE_{x-y}).

The coefficient of thermal expansion is an x-y direction coefficient of thermal expansion measured within a range of 25 °C to 150 °C.

In a process of forming two or more layers of the first complex insulating layer 20 on the glass core 10, the packaging substrate 100 may be repeatedly exposed to an atmosphere in which temperature rises and falls. At this time, when the first complex insulating layer 20 is excessively expanded in a high-temperature atmosphere, there may occur a problem that a wiring layer formed in the first complex insulating layer 20 (particularly, a wiring layer formed in a via pattern in the first complex insulating layer 20) is damaged. In addition, while respective layers constituting the first complex insulating layer 20 repeatedly thermally expand in a high-temperature atmosphere, the base insulating layer 22 and the elastic insulating layer 21 may be peeled from each other.

The present disclosure may control the Dcp value, which is a deviation in thermal expansion characteristic of the first complex insulating layer 20, within a specific range. In this case, an overall thermal expansion characteristic of the first complex insulating layer 20 may be controlled to a certain level or less, and peeling of the base insulating layer 22 from the elastic insulating layer 21 in a high-temperature atmosphere may be suppressed. At the same time, a magnitude of force applied to the glass core by formation of the first complex insulating layer may be effectively lowered.

The coefficients of thermal expansion of the elastic insulating layer 21 and the base insulating layer 22 are measured by a thermomechanical analyzer (TMA) using JIS-C6481 as a standard. Upon measurement, a tensile method is performed as prescribed in IPC-TM650, and a temperature increase rate is applied at 10 °C/min. The coefficients of thermal expansion are measured within a range of 25 °C to 150 °C.

A Dcp value, which is a deviation in thermal expansion characteristic of Equation 1 above, of the first complex insulating layer 20 may be 4 ppm/°C to 15 ppm/°C. The Dcp value may be 13 ppm/°C or less. The Dcp value may be 11 ppm/°C or less. The Dcp value may be 9 ppm/°C or less. The Dcp value may be 4.5 ppm/°C or more. The Dcp value may be 5 ppm/°C or more. The Dcp value may be 5.5 ppm/°C or more. The Dcp value may be 6 ppm/°C or more. In this case, even when the elastic insulating layer 21 having sufficient elasticity is applied to the first complex insulating layer 20, occurrence of interlayer peeling in the first complex insulating layer 20 or damage to an electrical connection in a high-temperature atmosphere may be suppressed.

An x-y direction coefficient of thermal expansion of the elastic insulating layer 21, measured within a range of 25 °C to 150 °C, may be 40 ppm/°C or more. The coefficient of thermal expansion may be 50 ppm/°C or more. The coefficient of thermal expansion may be 60 ppm/°C or more. The coefficient of thermal expansion may be 120 ppm/°C or less. The coefficient of thermal expansion may be 110 ppm/°C or less. The coefficient of thermal expansion may be 100 ppm/°C or less. In this case, an influence of thermal expansion behavior of the elastic insulating layer 21 on degradation of reliability of an electrical connection in the packaging substrate 100 may be lowered to a certain level or less.

An x-y direction coefficient of thermal expansion of the base insulating layer 22, measured within a range of 25 °C to 150 °C, may be 50 ppm/°C or less. The coefficient of thermal expansion may be 40 ppm/°C or less. The coefficient of thermal expansion may be 30 ppm/°C or less. The coefficient of thermal expansion may be 5 ppm/°C or more. In this case, the first complex insulating layer 20 may contribute to stably supporting and fixing a wiring layer even in a high-temperature atmosphere.

An elongation of the elastic insulating layer 21 may be 25% or more. The elongation of the elastic insulating layer 21 may be 35% or more. The elongation of the elastic insulating layer 21 may be 45% or more. The elongation of the elastic insulating layer 21 may be 55% or more. The elongation of the elastic insulating layer 21 may be 120% or less. The elongation of the elastic insulating layer 21 may be 100% or less. The elongation of the elastic insulating layer 21 may be 80% or less. The elastic insulating layer 21 having these characteristics may effectively lower a force applied to the glass core 10 when a plurality of first complex insulating layers 20 are formed, while contributing to suppressing separation of the base insulating layer 22 and the elastic insulating layer 21 or damage of the elastic insulating layer 21.

The elongation of the elastic insulating layer 21 is measured in Pull mode at 23 °C through a Universal Testing Machine (UTM). Upon measurement, the elongation is measured under conditions of a tensile speed of 1 mm/min and an average of N=5.

A ratio of a thickness of the elastic insulating layer 21 to a thickness of the base insulating layer 22 may be 0.05 to 0.3. The ratio may be 0.25 or less. The ratio may be 0.22 or less. The ratio may be 0.2 or less. The ratio may be 0.18 or less. The ratio may be 0.07 or more. The ratio may be 0.1 or more. In this case, while thermal expansion characteristics of the first complex insulating layer 20 are stably maintained, the elastic insulating layer 21 as a stress buffer layer may effectively relieve stress applied to the glass core 10.

A thickness of the elastic insulating layer 21 may be 1 μm or more. The thickness may be 2 μm or more. The thickness may be 3 μm or more. The thickness may be 15 μm or less. The thickness may be 12 μm or less. The thickness may be 10 μm or less. In this case, the elastic insulating layer 21 may have a thickness suitable for functioning as a stress buffer layer.

A thickness of the base insulating layer 22 may be 15 μm or more. The thickness may be 18 μm or more. The thickness may be 20 μm or more. The thickness may be 23 μm or more. The thickness may be 25 μm or more. The thickness may be 28 μm or more. The thickness may be 30 μm or more. The thickness may be 50 μm or less. In this case, the first complex insulating layer 20 may stably support a wiring layer.

When an entire surface of a wiring layer is surrounded by an insulating layer having high dielectric properties, significant signal loss may occur during signal transmission through the wiring layer. The present disclosure may allow smooth signal transmission of the wiring layer by causing the base insulating layer 22, of which dielectric properties are controlled, to surround a part of a surface of the wiring layer.

A dielectric constant Dk of the base insulating layer 22 at frequency of 5.8 GHz may be 4 or less. The Dk value may be 3.8 or less. The Dk value may be 3.6 or less. The Dk value may be 3.4 or less. The Dk value may be 1 or more.

A dielectric dissipation factor Df of the base insulating layer 22 at frequency of 5.8 GHz may be 0.01 or less. The Df value may be 0.008 or less. The Df value may be 0.006 or less. The Df value may be 0.004 or less. The Df value may be 0.001 or more. The Df value may be 0.002 or more.

In this case, stable signal transmission may be possible through the wiring layer formed on the first complex insulating layer 20 without excessive signal loss.

The Dk value and the Df value of the base insulating layer 22 are measured at room temperature using a dielectric property measuring instrument.

The present disclosure may adjust a ratio of thicknesses of the base insulating layer 22 and the elastic insulating layer 21 in the first complex insulating layer 20. In this case, excessive thermal expansion of the first complex insulating layer 20 in a thickness direction due to the elastic insulating layer 21 may be suppressed, and damage to an electrical connection formed in a through via in the first complex insulating layer 20 may be suppressed.

FIG. 2 is a cross-sectional view illustrating a packaging substrate according to another embodiment of the present disclosure. Hereinafter, the present disclosure will be described with reference to FIG. 2.

The packaging substrate 100 comprises a glass core 10 and a first complex insulating layer 20 disposed on the glass core 10. Regarding components of the packaging substrate 100, the descriptions above with reference to FIG. 1 are applied as they are. Hereinafter, differences will be mainly described.

The packaging substrate 100 may further comprise a wiring layer 30. The wiring layer 30 is a conductor transmitting an electrical signal. The wiring layer 30 may be electrically connected to a terminal and/or a device in the packaging substrate 100.

The wiring layer 30 may comprise an electrically conductive material. For example, the wiring layer 30 may comprise at least one of copper, nickel, aluminum, gold, or silver. Copper and the like may be applied as a material of the wiring layer 30.

The packaging substrate 100 may comprise the wiring layer 30 disposed on the first complex insulating layer 20. The packaging substrate 100 may further comprise the wiring layer 30 disposed in contact with an upper surface of the glass core 10. The first complex insulating layer 20 may comprise a through via (not shown). The packaging substrate 100 may further comprise the wiring layer 30 disposed in the through via.

The packaging substrate 100 may comprise two or more layers of the first complex insulating layer 20. The packaging substrate 100 may further comprise the wiring layer 30 disposed between the first complex insulating layers 20. The wiring layer 30 may be disposed while being mixed with the first complex insulating layer 20 disposed on the wiring layer 30. The wiring layer 30 may be disposed in a form embedded in the first complex insulating layer 20 disposed on the wiring layer 30. The first complex insulating layer 20 disposed on the wiring layer 30 may surround at least a part of an upper surface and/or a side surface of the wiring layer 30.

An upper surface of the wiring layer 30 may be in contact with a lower surface of the first complex insulating layer 20 disposed on the wiring layer 30. The upper surface of the wiring layer 30 may contact the lower surface of the first complex insulating layer 20 disposed on the wiring layer 30. A lower surface of the wiring layer 30 may contact an upper surface of the first complex insulating layer 20 disposed below the wiring layer 30.

A 90° peel strength of the wiring layer 30 with respect to the first complex insulating layer 20 disposed on the wiring layer 30 may be 1 kgf/cm or more. The peel strength may be 1.2 kgf/cm or more. The peel strength may be 1.4 kgf/cm or more. The peel strength may be 3 kgf/cm or less.

The upper surface of the wiring layer 30 may contact a lower surface of the elastic insulating layer 21 disposed on the wiring layer 30. A 90° peel strength of the wiring layer 30 with respect to the elastic insulating layer 21 disposed on the wiring layer 30 may be 1 kgf/cm or more. The peel strength may be 1.2 kgf/cm or more. The peel strength may be 1.4 kgf/cm or more. The peel strength may be 3 kgf/cm or less.

In this case, the wiring layer 30 may be stably supported and fixed in the packaging substrate 100, and may have stable electrical reliability.

The peel strength of the wiring layer 30 is measured by the following method.

A multilayer film comprising the wiring layer 30 and the first complex insulating layer 20 disposed in contact on the wiring layer 30 is peeled from the first complex insulating layer 20 disposed below the wiring layer 30. The multilayer film is turned over, and the peel strength of the wiring layer 30 is measured while peeling the wiring layer 30 from the first complex insulating layer 20. The peel strength of the wiring layer 30 is measured by a bond tester according to a 90° peel test. A measurement speed (peel speed) is set to 10 mm/s, and a measurement distance is set to 100 mm as a peel distance. For example, the peel strength value may be measured using a Condor Sigma bond tester manufactured by XYZ TEC.

FIG. 3 is a cross-sectional view illustrating a packaging substrate according to still another embodiment of the present disclosure. Hereinafter, the present disclosure will be described with reference to FIG. 3.

The packaging substrate 100 comprises a glass core 10 and a first complex insulating layer 20 disposed on the glass core 10. Regarding components of the packaging substrate 100, the descriptions above with reference to FIG. 2 are applied as they are. Hereinafter, differences will be mainly described.

The packaging substrate 100 may further comprise a second complex insulating layer 23 disposed below the glass core 10. The second complex insulating layer 23 may comprise the elastic insulating layer 21 and the base insulating layer 22 disposed below the elastic insulating layer 21. The elastic insulating layer 21 and the base insulating layer 22 included in the second complex insulating layer 23 respectively correspond to the elastic insulating layer 21 and the base insulating layer 22 described above. Descriptions of the elastic insulating layer 21 and the base insulating layer 22 included in the second complex insulating layer 23 are omitted because they overlap with the foregoing contents.

The packaging substrate 100 may further comprise a wiring layer (not shown) disposed in contact with a lower surface of the glass core 10. The packaging substrate 100 may further comprise a wiring layer (not shown) disposed below the second complex insulating layer 23.

The packaging substrate 100 may comprise two or more layers of each of the first complex insulating layer 20 and the second complex insulating layer 23. In the present disclosure, the first complex insulating layer 20 and the second complex insulating layer 23, to which the elastic insulating layer 21 is applied, may be multilayer-stacked above and below the glass core 10. In this case, even when insulating layers are multilayer-stacked on the glass core 10, excessive warpage of the glass core 10 may be suppressed.

A ratio of a sum of overall thicknesses of the first complex insulating layer 20 and the second complex insulating layer 23 to a thickness of the glass core 10 may be 0.7 or more. The ratio may be 0.75 or more. The ratio may be 0.8 or more. The ratio may be 2 or less. The ratio may be 1.8 or less. The packaging substrate 100 of the present disclosure may have stable flatness even when such ratio is applied.

### Composition of Complex Insulating Layer

The elastic insulating layer 21 may comprise a bis-maleimide resin. The bis-maleimide resin may impart elastic properties suitable for the elastic insulating layer 21 to function as a stress buffer layer in the complex insulating layer. In addition, the bis-maleimide resin may allow the elastic insulating layer 21 to have excellent bonding strength with respect to the wiring layer 30, thereby helping the wiring layer 30 to be stably fixed to the elastic insulating layer 21 even without excessively roughening a surface of the wiring layer 30. In this case, the packaging substrate 100 may have much less signal loss than a packaging substrate 100 using the excessively roughened wiring layer 30 when driven by applying high-frequency power.

A number average molecular weight of the bis-maleimide resin may be 4,000 or more. The number average molecular weight may be 7,000 or more. The number average molecular weight may be 10,000 or more. The number average molecular weight may be 15,000 or more. The number average molecular weight may be 50,000 or less. The number average molecular weight may be 45,000 or less. The number average molecular weight may be 40,000 or less. The number average molecular weight may be 35,000 or less.

The number average molecular weight of the bis-maleimide resin is measured by gel permeation chromatography (GPC).

The bis-maleimide resin may have a dimer acid skeleton. The bis-maleimide resin may be a resin formed through a reaction of an acid anhydride and a diamine.

The elastic insulating layer 21 may further comprise an epoxy resin. The elastic insulating layer 21 may further comprise a cured epoxy resin. The epoxy resin may be any one selected from the group consisting of a bisphenol-type epoxy resin, a novolak-type epoxy resin, a biphenyl-type epoxy resin, an arylalkylene-type epoxy resin, a tetraphenylolethane-type epoxy resin, a naphthalene-type epoxy resin, an anthracene-type epoxy resin, a phenoxy-type epoxy resin, a dicyclopentadiene-type epoxy resin, a norbornene-type epoxy resin, and combinations thereof.

The elastic insulating layer 21 may comprise 0.1 parts by weight or more of an epoxy resin based on 100 parts by weight of the bis-maleimide resin. The elastic insulating layer 21 may comprise 1 part by weight or more of an epoxy resin based on 100 parts by weight of the bis-maleimide resin. The elastic insulating layer 21 may comprise 5 parts by weight or more of an epoxy resin based on 100 parts by weight of the bis-maleimide resin. The elastic insulating layer 21 may comprise 15 parts by weight or less of an epoxy resin based on 100 parts by weight of the bis-maleimide resin. The elastic insulating layer 21 may comprise 10 parts by weight or less of an epoxy resin based on 100 parts by weight of the bis-maleimide resin. In this case, the elastic insulating layer 21 may be helped to have flexibility suitable for application to the first complex insulating layer 20 and the like and bonding strength with respect to the wiring layer 30.

The elastic insulating layer 21 may further comprise a filler. The filler may comprise an inorganic filler. The inorganic filler may be any one selected from the group consisting of barium sulfate, silica, talc, clay, magnesium carbonate, calcium carbonate, aluminum oxide, aluminum hydroxide, silicon nitride, aluminum nitride, titanium oxide, and combinations thereof.

The elastic insulating layer 21 may further comprise additives other than the components described above. The additives are not limited so long as they are commonly applied in the packaging substrate field. Examples of the additives include a curing agent, a colorant, and/or an antifoaming agent.

The base insulating layer 22 may comprise an epoxy resin and a filler. The base insulating layer 22 may comprise a cured epoxy resin and a filler.

The epoxy resin described above may be applied as the epoxy resin. Description of the epoxy resin is omitted because it overlaps with the foregoing contents.

The base insulating layer 22 may comprise 10 wt % or more of an epoxy resin. The base insulating layer 22 may comprise 15 wt % or more of an epoxy resin. The base insulating layer 22 may comprise 20 wt % or more of an epoxy resin. The base insulating layer 22 may comprise 50 wt % or less of an epoxy resin. The base insulating layer 22 may comprise 45 wt % or less of an epoxy resin. The base insulating layer 22 may comprise 40 wt % or less of an epoxy resin.

The base insulating layer 22 may comprise a filler. The base insulating layer 22 may comprise the filler described above. Description of the filler is omitted because it overlaps with the foregoing description.

The base insulating layer 22 may further comprise additives other than the components described above. The additives are not limited so long as they are commonly applied in the packaging substrate field. Examples of the additives include a curing agent, a colorant, and/or an antifoaming agent.

### Semiconductor Package

A semiconductor package according to still another embodiment of the present disclosure comprises a packaging substrate and a device electrically connected to the packaging substrate.

The packaging substrate may be mounted on a main board and may be electrically connected to the main board.

Descriptions of the packaging substrate and the device are omitted because they overlap with the foregoing contents.

### Method for Manufacturing Packaging Substrate

A method for manufacturing a packaging substrate according to still another embodiment of the present disclosure is a method for manufacturing a packaging substrate, comprising a complex insulating layer forming step of forming a complex insulating layer on a glass core.

Description of the glass core is omitted because it overlaps with the foregoing contents.

As necessary, a glass core on which a wiring layer is formed on an upper surface may be provided.

The complex insulating layer forming step may comprise an elastic insulating layer forming process of forming an elastic insulating layer on the glass core, and a base insulating layer forming process of forming a base insulating layer on the elastic insulating layer.

The elastic insulating layer forming process may be performed by laminating and curing a film for forming an elastic insulating layer on the glass core, or may be performed by coating a composition for forming an elastic insulating layer on the glass core and then curing the same.

The film for forming an elastic insulating layer or the composition for forming an elastic insulating layer may comprise a bis-maleimide resin. The number average molecular weight of the bis-maleimide resin may be 4,000 or more. The number average molecular weight may be 7,000 or more. The number average molecular weight may be 10,000 or more. The number average molecular weight may be 15,000 or more. The number average molecular weight may be 50,000 or less. The number average molecular weight may be 45,000 or less. The number average molecular weight may be 40,000 or less. The number average molecular weight may be 35,000 or less.

The number average molecular weight of the bis-maleimide resin is measured by gel permeation chromatography (GPC).

The bis-maleimide resin may have a dimer acid skeleton. The bis-maleimide resin may be a resin formed through a reaction of an acid anhydride and a diamine.

The film for forming an elastic insulating layer or the composition for forming an elastic insulating layer may further comprise an epoxy resin. The epoxy resin may be any one selected from the group consisting of a bisphenol-type epoxy resin, a novolak-type epoxy resin, a biphenyl-type epoxy resin, an arylalkylene-type epoxy resin, a tetraphenylolethane-type epoxy resin, a naphthalene-type epoxy resin, an anthracene-type epoxy resin, a phenoxy-type epoxy resin, a dicyclopentadiene-type epoxy resin, a norbornene-type epoxy resin, and combinations thereof.

The film for forming an elastic insulating layer or the composition for forming an elastic insulating layer may comprise 0.1 parts by weight or more of the epoxy resin based on 100 parts by weight of the bis-maleimide resin. The film for forming an elastic insulating layer or the composition for forming an elastic insulating layer may comprise 1 part by weight or more of the epoxy resin based on 100 parts by weight of the bis-maleimide resin. The film for forming an elastic insulating layer or the composition for forming an elastic insulating layer may comprise 5 parts by weight or more of the epoxy resin based on 100 parts by weight of the bis-maleimide resin. The film for forming an elastic insulating layer or the composition for forming an elastic insulating layer may comprise 15 parts by weight or less of the epoxy resin based on 100 parts by weight of the bis-maleimide resin. The film for forming an elastic insulating layer or the composition for forming an elastic insulating layer may comprise 10 parts by weight or less of the epoxy resin based on 100 parts by weight of the bis-maleimide resin. In this case, the elastic insulating layer may be helped to have physical properties suitable for functioning as a buffer layer for lowering stress of the glass core and for fixing the wiring layer.

The film for forming an elastic insulating layer or the composition for forming an elastic insulating layer may further comprise a filler. The elastic insulating layer may comprise the filler described above. Description of the filler in the elastic insulating layer is omitted because it overlaps with the foregoing description.

The film for forming an elastic insulating layer or the composition for forming an elastic insulating layer may further comprise additives other than the components described above. The additives are not limited so long as they are commonly applied in the packaging substrate field. Examples of the additives include a curing agent, a colorant, and/or an antifoaming agent.

The elastic insulating layer may be formed by laminating a film for forming an elastic insulating layer on the glass core and curing the film.

Specifically, the film for forming an elastic insulating layer may be laminated by vacuum-adhering the film for forming an elastic insulating layer onto an upper surface of the glass core, and then hot-press adhering the same.

Vacuum adhesion of the film for forming an elastic insulating layer may be performed for 10 seconds or more. Vacuum adhesion of the film for forming an elastic insulating layer may be performed for 20 seconds or more. Vacuum adhesion of the film for forming an elastic insulating layer may be performed for 120 seconds or less.

Vacuum adhesion of the film for forming an elastic insulating layer may be performed in an atmosphere of 50 °C or more. Vacuum adhesion of the film for forming an elastic insulating layer may be performed in an atmosphere of 60 °C or more. Vacuum adhesion of the film for forming an elastic insulating layer may be performed in an atmosphere of 150 °C or less. Vacuum adhesion of the film for forming an elastic insulating layer may be performed in an atmosphere of 140 °C or less.

A press pressure during vacuum adhesion of the film for forming an elastic insulating layer may be 0.05 MPa or more. The press pressure may be 0.1 MPa or more. The press pressure may be 1 MPa or less.

When hot-press adhering the film for forming an elastic insulating layer, a hot-press temperature may be 70 °C or more. The hot-press temperature may be 80 °C or more. The hot-press temperature may be 200 °C or less. The hot-press temperature may be 180 °C or less.

Pressure applied when hot-press adhering the film for forming an elastic insulating layer may be 1 kgf/cm² or more. The pressure may be 3 kgf/cm² or more. The pressure may be 10 kgf/cm² or less.

Hot-press adhesion of the film for forming an elastic insulating layer may be performed for 10 seconds or more. Hot-press adhesion of the film for forming an elastic insulating layer may be performed for 20 seconds or more. Hot-press adhesion of the film for forming an elastic insulating layer may be performed for 90 seconds or less.

The elastic insulating layer may be formed by curing the laminated film for forming an elastic insulating layer.

Curing of the film for forming an elastic insulating layer may be performed through two or more heat treatment processes.

In a first heat treatment process, an atmosphere temperature may be 90 °C or more. The atmosphere temperature may be 100 °C or more. The atmosphere temperature may be 110 °C or more. The atmosphere temperature may be 150 °C or less.

The first heat treatment process may be performed for 10 minutes or more. The first heat treatment process may be performed for 15 minutes or more. The first heat treatment process may be performed for 20 minutes or more. The first heat treatment process may be performed for 60 minutes or less.

In a second heat treatment process, an atmosphere temperature may be 110 °C or more. The atmosphere temperature may be 120 °C or more. The atmosphere temperature may be 130 °C or more. The atmosphere temperature may be 200 °C or less.

The second heat treatment process may be performed for 10 minutes or more. The second heat treatment process may be performed for 15 minutes or more. The second heat treatment process may be performed for 20 minutes or more. The second heat treatment process may be performed for 60 minutes or less.

The base insulating layer forming process may be performed by laminating a film for forming a base insulating layer on the elastic insulating layer or on a film for manufacturing an elastic insulating layer, or by coating a composition for forming a base insulating layer, and then curing the film or composition.

The film or composition for manufacturing a base insulating layer may comprise an epoxy resin and a filler.

The epoxy resin described above may be applied as the epoxy resin. Description of the epoxy resin is omitted because it overlaps with the foregoing contents.

The film for manufacturing a base insulating layer may comprise 10 wt % or more of an epoxy resin. The film for manufacturing a base insulating layer may comprise 15 wt % or more of an epoxy resin. The film for manufacturing a base insulating layer may comprise 20 wt % or more of an epoxy resin. The film for manufacturing a base insulating layer may comprise 50 wt % or less of an epoxy resin. The film for manufacturing a base insulating layer may comprise 45 wt % or less of an epoxy resin. The film for manufacturing a base insulating layer may comprise 40 wt % or less of an epoxy resin.

The film for manufacturing a base insulating layer may comprise a filler. The film for manufacturing a base insulating layer may comprise the filler described above. Description of the filler is omitted because it overlaps with the foregoing description.

The film for manufacturing a base insulating layer may further comprise additives other than the components described above. The additives are not limited so long as they are commonly applied in the buildup film field. Examples of the additives include a curing agent, a colorant, and an antifoaming agent.

The base insulating layer may be formed by laminating a film for forming a base insulating layer on the elastic insulating layer or on the film for manufacturing an elastic insulating layer, and curing the same.

The film for forming a base insulating layer may be disposed in a region where the base insulating layer is to be formed, and may be laminated by vacuum-adhering the film and then hot-press adhering the same.

When vacuum-adhering the film for forming abase insulating layer, a time during which vacuum pressure is applied may be 10 seconds or more. The time may be 20 seconds or more. The time may be 90 seconds or less.

When hot-press adhering the film for forming a base insulating layer, a hot-press temperature may be 70 °C or more. The hot-press temperature may be 80 °C or more. The hot-press temperature may be 200 °C or less. The hot-press temperature may be 180 °C or less.

Pressure applied when hot-press adhering the film for forming a base insulating layer may be 3 kgf/cm² or more. The pressure may be 5 kgf/cm² or more. The pressure may be 20 kgf/cm² or less.

After laminating the film for forming a base insulating layer, the laminated film for forming a base insulating layer may be additionally hot-press adhered.

Pressure applied when additionally hot-press adhering the film for forming a base insulating layer may be 1 kgf/cm² or more. The pressure may be 3 kgf/cm² or more. The pressure may be 10 kgf/cm² or less.

When additionally hot-press adhering the film for forming a base insulating layer, a hot-press temperature may be 70 °C or more. The hot-press temperature may be 80 °C or more. The hot-press temperature may be 200 °C or less. The hot-press temperature may be 180 °C or less.

When additionally hot-press adhering the film for forming a base insulating layer, a time during which pressure is applied may be 10 seconds or more. The time may be 20 seconds or more. The time may be 90 seconds or less.

The base insulating layer may be formed by curing the laminated film for forming abase insulating layer.

Curing of the film for forming a base insulating layer may be performed through two or more heat treatment processes.

In a first heat treatment process, an atmosphere temperature may be 90 °C or more. The atmosphere temperature may be 100 °C or more. The atmosphere temperature may be 110 °C or more. The atmosphere temperature may be 150 °C or less.

The first heat treatment process may be performed for 10 minutes or more. The first heat treatment process may be performed for 15 minutes or more. The first heat treatment process may be performed for 20 minutes or more. The first heat treatment process may be performed for 60 minutes or less.

In a second heat treatment process, an atmosphere temperature may be 110 °C or more. The atmosphere temperature may be 120 °C or more. The atmosphere temperature may be 130 °C or more. The atmosphere temperature may be 200 °C or less.

The second heat treatment process may be performed for 10 minutes or more. The second heat treatment process may be performed for 15 minutes or more. The second heat treatment process may be performed for 20 minutes or more. The second heat treatment process may be performed for 60 minutes or less.

The first complex insulating layer may be formed by forming the elastic insulating layer and forming the base insulating layer on the elastic insulating layer.

The first complex insulating layer may be formed by laminating and curing a film for manufacturing an elastic insulating layer, and then laminating and curing a film for manufacturing a base insulating layer on the elastic insulating layer, or may be formed by laminating the film for manufacturing an elastic insulating layer and the film for manufacturing a base insulating layer, and then simultaneously curing the two films.

As necessary, after forming a wiring layer on the first complex insulating layer, another first complex insulating layer may be formed on the wiring layer so as to surround the wiring layer, thereby forming a redistribution layer on the glass core.

The wiring layer may be formed by a dry method or a wet method.

The dry method is a method of forming a seed layer by performing sputtering in a region where the wiring layer is to be disposed, and forming the wiring layer by performing plating in the region where the seed layer is formed. When forming the seed layer, a metal such as titanium, chromium, or nickel may be sputtered, and copper may be applied together with the metals and sputtered. Through sputtering, an anchor effect in which a surface of the glass core or the first complex insulating layer and metal particles interact may appear, thereby improving adhesion of the wiring layer.

The wet method is a method of treating a primer on a portion where formation of the wiring layer is required, and then forming seed layer and performing metal plating. The primer may comprise a compound having a functional group such as an amine. Depending on a degree of intended adhesion strength, the primer may comprise together a compound having a functional group such as an amine and a silane coupling agent. When the silane coupling agent is applied, a primer layer may be formed by pre-treating a surface to be primer-treated with the silane coupling agent and then coating the pre-treated region with a compound having an amine group.

After forming the seed layer, the wiring layer may be formed by plating a metal. Copper plating may be applied when forming the wiring layer, but is not limited thereto. Before metal plating, a portion in the seed layer where formation of the wiring layer is not required may be inactivated, or a portion where formation of the wiring layer is required may be activated, and then plating may be performed. As an activation or inactivation treatment method, a light irradiation treatment of irradiating a laser having a specific wavelength and the like, a chemical treatment, and the like may be applied. However, after performing metal plating without applying the activation or inactivation treatment, the wiring layer may be patterned by etching according to a pre-designed shape.

After forming the wiring layer, the first complex insulating layer surrounding the wiring layer may be formed. The first complex insulating layer formed on the wiring layer may be formed by the same method as described above.

As necessary, a second complex insulating layer may be formed below the glass core by using the method applied to formation of the first complex insulating layer. The second complex insulating layer may be manufactured by the same method as the method of forming the first complex insulating layer, except that the base insulating layer is formed below the elastic insulating layer. Description of the method for forming the second complex insulating layer is omitted because it overlaps with the foregoing contents.

The method for manufacturing a packaging substrate of the present disclosure may further comprise forming connection terminals, bumps, a cover layer, and the like on an upper surface and/or a lower surface of the packaging substrate, or a process of mounting a device on the substrate.

Hereinafter, the present disclosure will be described in more detail through specific Examples. The following Examples are merely examples for helping understanding of the present disclosure, and the scope of the present disclosure is not limited thereto.

### Preparation Example: Manufacture of Packaging Substrate

Example 1: An SLK-214 film manufactured by Shin-Etsu, which is a film for forming an elastic insulating layer, was laminated on a glass substrate having a thickness of 650 m. Specifically, the film for forming an elastic insulating layer was vacuum-adhered for 30 seconds at a pressure of 0.3 MPa in an atmosphere of 80 °C under a reduced-pressure atmosphere, and then hot-press adhered to the film for forming an elastic insulating layer for 30 seconds at a temperature of 120 °C and a pressure of 3 kgf/cm².

A GL103 film manufactured by AFT, which is a film for forming abase insulating layer, was laminated on the laminated film for forming an elastic insulating layer. After vacuum-adhering the laminated film for forming a base insulating layer for 30 seconds under a reduced-pressure atmosphere, hot-press adhesion was performed to the film for forming a base insulating layer at a temperature of 120 °C and a pressure of 7 kgf/cm². Thereafter, hot-press adhesion was further applied to the film for forming a base insulating layer for 60 seconds at a temperature of 120 °C and a pressure of 5 kgf/cm².

In the same manner, seven layers each of the film for forming an elastic insulating layer and the film for forming a base insulating layer were alternately laminated on the glass core, and seven layers each of the film for forming an elastic insulating layer and the film for forming a base insulating layer were alternately laminated below the glass core.

Thereafter, the substrate was heat-treated at 130 °C for 30 minutes and heat-treated at 165 °C for 30 minutes to form the first complex insulating layer and the second complex insulating layer, and the substrate was singulated to manufacture a packaging substrate. In the packaging substrate, a thickness of the elastic insulating layer was observed to be 5 μm, and a thickness of the base insulating layer was observed to be 35 μm.
Example 2: A packaging substrate was manufactured under the same conditions as in Example 1, except that the film for forming an elastic insulating layer was changed to an SLK-215 film manufactured by Shin-Etsu, and an atmosphere temperature during vacuum adhesion of the film for forming an elastic insulating layer was changed to 120 °C. In the packaging substrate, a thickness of the elastic insulating layer was observed to be 5 μm, and a thickness of the base insulating layer was observed to be 35 μm.
Example 3: A copper foil having a thickness of 20 μm and having a surface roughened so that an arithmetic average roughness Ra became 500 nm was prepared. A film for forming an elastic insulating layer and a film for forming a base insulating layer on the film for forming an elastic insulating layer were laminated on an upper surface of the copper foil under the same conditions as in Example 1. Thereafter, the copper foil laminate was heat-treated under the same conditions as in Example 1 to form the elastic insulating layer and the base insulating layer.
Comparative Example 1: A packaging substrate was manufactured under the same conditions as in Example 1, except that the film for forming an elastic insulating layer was not applied. In the packaging substrate, a thickness of the base insulating layer was observed to be 35 μm.

### Evaluation Example: Measurement of Properties of Each Insulating Layer

In the packaging substrates of Examples and Comparative Example, the elastic insulating layer and the base insulating layer were cut and used as test specimens. Using a thermomechanical analyzer (TMA) with JIS-C6481 as a standard, glass transition temperatures and coefficients of thermal expansion of the elastic insulating layer and the base insulating layer of each of Examples and Comparative Example were measured, and Dcp values were calculated. Upon measurement, a tensile method was performed as prescribed in IPC-TM650, and a temperature increase rate was applied at 10 °C/min. The glass transition temperatures and coefficients of thermal expansion were measured within a range of 25 °C to 150 °C.

Thereafter, elongation of the elastic insulating layer of each of Examples and Comparative Example was measured in Pull mode at 23 °C using a Universal Testing Machine (UTM). Upon measurement, the elongation was measured under conditions of a tensile speed of 1 mm/min and an average of N=5.

Further, dielectric constant Dk at frequency of 5.8 GHz and dielectric dissipation factor Df at frequency of 5.8 GHz of the base insulating layer of each of Examples and Comparative Example were measured at room temperature using a dielectric property measuring instrument.

In Example 3, while peeling the copper foil from the elastic insulating layer, a 90° peel strength of the copper foil with respect to the elastic insulating layer was measured. The 90° peel strength of the copper foil was measured using a Condor Sigma bond tester manufactured by XYZ TEC according to a 90° peel test. A measurement speed was set to 10 mm/s, and a measurement distance was set to 100 mm. When the measured value was 1 kgf/cm or more, it was evaluated as Pass, and when the measured value was less than 1 kgf/cm, it was evaluated as Fail.

Measured values and evaluation results of each insulating layer for Examples and Comparative Example are shown in Table 1 below.

### Evaluation Example: Warpage Evaluation

During the manufacturing process of the packaging substrates of Examples 1 and 2 and Comparative Example 1, warpage of the substrate was evaluated before singulation was performed. Specifically, after placing the substrate on a flat floor surface, a height by which an edge of the substrate was lifted from the floor surface was measured. A maximum value of the measured height values is shown in Table 2 below.

TABLE 1

| | | | | CTE of | CTE of | |
|---|---|---|---|---|---|---|
| | Tg of | | | Elastic | Base | Elongation |
| | Elastic | Tg of Base | | Insulating | Insulating | of Elastic |
| | Insulating | Insulating | Dcp | Layer | Layer | Insulating |
| | Layer (°C) | Layer (°C) | (ppm/°C) | (ppm/°C) | (ppm/°C) | Layer (%) |
| Example 1 | 50 | 165 | 6.875 | 85 | 20 | 40 |
| Example 2 | 60 | 165 | 6.875 | 85 | 20 | 75 |
| Example 3 | 50 | 165 | 6.875 | 85 | 20 | 40 |
| Comparative | — | 165 | — | — | 20 | — |
| Example 1 | | | | | | |

TABLE 2

| | Dk of Base | Df of Base | Peel Strength | Warpage |
|---|---|---|---|---|
| | Insulating | Insulating | Evaluation of | Evaluation |
| | Layer | Layer | Wiring Layer | (mm) |
| Example 1 | 3.3 | 0.0036 | — | 4.5 |
| Example 2 | 3.3 | 0.0036 | — | 5.0 |
| Example 3 | 3.3 | 0.0036 | Pass | — |
| Comparative | 3.3 | 0.0036 | — | 12 |
| Example 1 | | | | |

Referring to Table 3 above, in the warpage evaluation, Examples 1 and 2 showed measured values of 5 mm or less, whereas Comparative Example 1 showed a measured value exceeding 10 mm.

### DESCRIPTION OF REFERENCE NUMERALS

100: packaging substrate
10: glass core
20: first complex insulating layer
21: elastic insulating layer
22: base insulating layer
23: second complex insulating layer
30: wiring layer

What is claimed is:

1. A packaging substrate, comprising:
a glass core; and
a first complex insulating layer disposed on the glass core,
wherein the first complex insulating layer comprises an elastic insulating layer and a base insulating layer disposed on the elastic insulating layer,
wherein a ratio of a thickness of the glass core to a thickness of the first complex insulating layer is 8 to 30, and
wherein a glass transition temperature of the elastic insulating layer is 30 °C to 85 °C.

2. The packaging substrate of claim 1,
wherein a Dcp value, which is a deviation in thermal expansion characteristic of Equation 1 below, of the first complex insulating layer is 4 ppm/°C to 15 ppm/°C;
Dcp=Tr_{b}×CTE_{b}−Trₑ×CTEₑ [Equation 1]
wherein in Equation 1,
the Tr_{b} is a ratio of a thickness of the base insulating layer to the thickness of the first complex insulating layer,
the CTE_{b} is a coefficient of thermal expansion of the base insulating layer measured at 25 °C to 150 °C (unit: ppm/°C),
the Trₑ is a ratio of a thickness of the elastic insulating layer to the thickness of the first complex insulating layer, and
the CTEₑ is a coefficient of thermal expansion of the elastic insulating layer measured at 25 °C to 150 °C (unit: ppm/°C).

3. The packaging substrate of claim 1,
wherein an elongation of the elastic insulating layer is 25% or more.

4. The packaging substrate of claim 1,
wherein a ratio of a thickness of the elastic insulating layer to a thickness of the base insulating layer is 0.05 to 0.3.

5. The packaging substrate of claim 1,
wherein a thickness of the elastic insulating layer is 1 μm to 15 μm.

6. The packaging substrate of claim 1,
wherein the elastic insulating layer is disposed in contact with at least a part of an upper surface of the glass core.

7. The packaging substrate of claim 1,
wherein a dielectric constant Dk of the base insulating layer at 5.8 GHz is 4 or less.

8. The packaging substrate of claim 1,
wherein a dielectric dissipation factor Df of the base insulating layer at 5.8 GHz is 0.01 or less.

9. The packaging substrate of claim 1,
wherein the elastic insulating layer comprises a bis-maleimide resin.

10. The packaging substrate of claim 1,
comprising two or more layers of the first complex insulating layer,
further comprising a wiring layer disposed between the first complex insulating layers,
wherein an upper surface of the wiring layer is disposed in contact with a lower surface of the first complex insulating layer disposed on the wiring layer, and
wherein a 90° peel strength of the wiring layer with respect to the first complex insulating layer disposed on the wiring layer is 1 kgf/cm or more.
